(19) United States
(12) Patent Application Publication
(10) Pub. No.: US 2013/0147026 A1
(43) Pub. Date: Jun. 13, 2013

(54) HEATSINK INTERPOSER

(71) Applicants: Roden R. TOPACIO, Markham (CA); Liane Martinez, Newmarket (CA); Yip Seng Low, Thornhill (CA)

(72) Inventors: Roden R. TOPACIO, Markham (CA); Liane Martinez, Newmarket (CA); Yip Seng Low, Thornhill (CA)

(73) Assignee: ATI Technologies ULC, Markham (CA)

(21) Appl. No.: 13/323,177

(22) Filed: Dec. 12, 2011

(51) Int. Cl. H01L 23/36; H01L 23/48

(52) U.S. Cl. 257/698; 257/690; 257/E23.101; 257/E23.021

(57) ABSTRACT

According an embodiment, a package-on-package heatsink interposer for use between a top package and a bottom package of a package-on-package device, may include a top heatsink below the top package; an interposer substrate below the top heatsink; a bottom heatsink below the interposer substrate; a first interposer substrate metal layer between the interposer substrate and the top heatsink; a second interposer substrate metal layer between the interposer substrate and the bottom heatsink; and interposer solder balls between the second interposer substrate metal layer and the bottom package.

### BACKGROUND

Package-on-package (POP) structures are designed for products with package area imitations but with few vertical size limitations. Devices, such as mobile phones, digital cameras, and other portable devices that have horizontal size limitations, can include POP structures. POP structures can save horizontal space in a device by vertically stacking packages on top of one another rather than placing packages horizontally adjacent to one another.

A POP configuration can include two or more ball grid arrays (BGA) stacked on top of one another. In a two-piece assembly, the bottom package can include a logic device, and the top package can include a memory device.

In order to affix the top package to the bottom package, a mold compound can be used. The mold compound can be applied to a center portion of the bottom package and can cover the die of the bottom package.

A problem associated with POP structures includes heat and warping. Heat can cause warping by causing one portion of the POP structure to expand faster and larger than other portions of the POP structure. For example, mismatches in thermal expansion of the die, the molding compound, and/or the substrate can cause warping. Bottom substrates of bottom packages can be especially prone to warping, for example, because the molding compound on the die has a different coefficient of thermal expansion compared to the die of the bottom package. For this reason, die sizes are often limited to reduce warping effects on the dies, especially the dies located on the bottom package.

### SUMMARY OF EMBODIMENTS

According to one embodiment, a device may include a package-on-package structure including a top package and a bottom package; and a heatsink interposer located between the top package and the bottom package, where the heatsink interposer includes: a heatsink; an interposer substrate; and interposer solder balls.

According to another embodiment, a package-on-package structure may include a top package; a heatsink interposer, where the heatsink interposer is under the top package and the heatsink interposer, including: an interposer substrate; a top heatsink between the top package and the interposer substrate; a bottom heatsink between the bottom package and the interposer substrate; and interposer solder balls between the bottom package and the interposer substrate; and a bottom package under the heatsink interposer.

According to still another embodiment, a package-on-package heatsink interposer for use between a top package and a bottom package of a package-on-package device, may include a top heatsink below the top package; an interposer substrate below the top heatsink; a bottom heatsink below the interposer substrate; a first interposer substrate metal layer between the interposer substrate and the top heatsink; a second interposer substrate metal layer between the interposer substrate and the bottom heatsink; and interposer solder balls between the second interposer substrate metal layer and the bottom package.

### BRIEF DESCRIPTION OF THE DRAWINGS

The accompanying drawings, which are incorporated in and constitute a part of this specification, illustrate one or more embodiments described herein and, together with the description, explain these embodiments. In the drawings:

FIG. 1A is a diagram of an example package-on-package structure according to an embodiment described herein;

FIG. 1B is a diagram of an example package-on-package structure according to an embodiment described herein;

FIG. 2 is a diagram of an example heatsink interposer according to an embodiment described herein;

FIG. 3A is a diagram of an example package-on-package structure with capillary underfill;

FIG. 3B is a diagram of an example package-on-package structure with capillary underfill and a heatsink interposer according to an embodiment described herein;

FIG. 4A is a diagram of an example package-on-package structure with mold underfill;

FIG. 4B is a diagram of an example package-on-package structure with mold underfill and a heatsink interposer according to an embodiment described herein;

FIG. 5A is a diagram of an example package-on-package structure with capillary underfill;

FIG. 5B is a diagram of an example package-on-package structure with capillary underfill and an increased die size;

FIG. 5C is a diagram of an example package-on-package structure with capillary underfill, an increased die size, and a heatsink interposer according to an embodiment described herein;

FIG. 6A is a diagram of an example package-on-package structure with capillary underfill;

FIG. 6B is a diagram of an example side-by-side structure with capillary and a heatsink; and

FIG. 6C is a diagram of an example package-on-package structure with capillary underfill, an increased die size, increased thermal dissipation requirement, and a heatsink interposer according to an embodiment described herein.

### DETAILED DESCRIPTION

The following detailed description refers to the accompanying drawings. The same reference numbers in different drawings may identify the same or similar elements.

### Overview

Systems and/or methods described herein may utilize a heatsink interposer to provide temperature regulation, accommodation of die sizes for varying sized top and bottom packages, and provide increased stiffness. Systems and/or methods described herein may also utilize a heatsink interposer to enable higher power and larger dies in a POP structure with smaller footprints.

### Example Arrangement

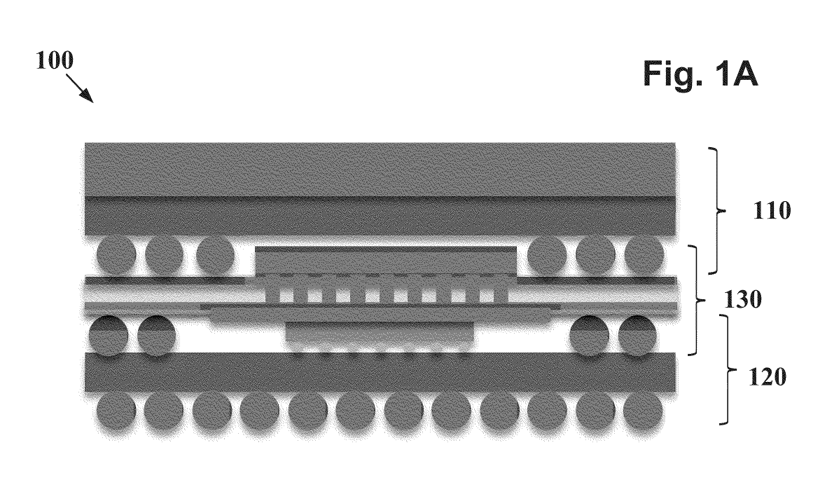

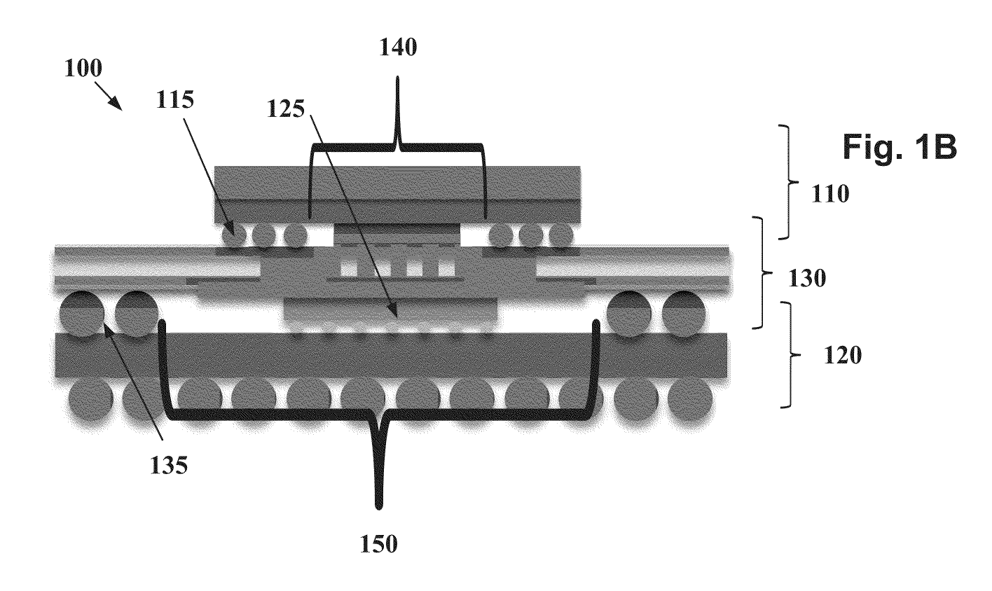

FIG. 1A is a diagram of an example POP structure 100 according to an embodiment described herein. As shown, POP structure 100 may include a top package 110, a bottom package 120, and a heatsink interposer 130.

Top package 110 may include any mechanically mating device. In one implementation, top package 110 can include a memory device that can work with a logic device bottom package 120. Top package 110 can be any size capable of fitting on heatsink interposer 110. In one implementation, top package 110, bottom package 120, and heatsink interposer 130 can be approximately the same length and width. For example, top package 110, bottom package 120, and heatsink interposer 130 can be 10-17 mm in length and width, (e.g., top package 110, bottom package 120, and heatsink interposer 130 can be 12 mm×12 mm).

In one implementation, top package 110, bottom package 120, and heatsink interposer 130 can be approximately the same height. For example, top package 110, bottom package 120, and heatsink interposer 130 can have a height of 500-1500 microns (e.g., 1000 microns). In another implementation, the height of the heatsink interposer 130 can be different from the top package 110 and/or the bottom package 120. For example, top package 110 can have a height of 1000 microns, bottom package 120 can have a height of 800 microns, and heatsink interposer 130 can have a height of 500 microns.

Bottom package 120 may include any mechanically mating device. In one implementation, bottom package 120 can include a logic device with a die on a top portion of the bottom package 120. In one implementation, the die can be any size smaller than bottom package 120. For example, the die can be 5-15 mm in length and width, and 150-250 microns in height (e.g., bottom package 120 can be 15 mm×15 mm×1000 microns and the die can be 10 mm×10 mm×200 microns).

Heatsink interposer 130 may include a structure that can provide heat dispersal, heat dissipation, and structural support for POP structure 100. In one implementation, heatsink interposer 130 can include a bottom ball footprint to accommodate a die size of bottom package 120, while having the space on a top portion of heatsink interposer 130 to accommodate the ball footprint of top package 110. For example, heatsink interposer 130 can include a bottom ball footprint that includes a space of 10 mm×10 mm to accommodate a die of 8 mm×8 mm, and can include space around a top portion of heatsink interposer 130 to accommodate solder balls on top package 110.

In another implementation, as illustrated in FIG. 1B, POP structure 100 can be provided with a bottom package 120 that is larger than a top package 110 and heatsink interposer 130 between bottom package 120 and top package 110. Bottom package 120 may be larger than top package 110 for any number of reasons. For example, bottom package 120 may be larger than top package 110 to accommodate a larger die size, a smaller top package 110 may be desirable for cost reasons, etc.

As illustrated in FIG. 1B, heatsink interposer 130 can be manufactured to accommodate the size of die 125 and bottom package 120 and also accommodate top package solder balls 115 and top package 110. For example, heatsink interposer 130 can include solder balls on a bottom surface with an area between interposer solder balls 135 that can accommodate the die 125 in bottom package 120 and a top surface with an area to accommodate solder balls 115 of top package 110. As further illustrated in FIG. 1B, die 125 can be larger than an area 140 between solder balls 115 and die 125 can be smaller than an area 150 between solder balls 135 on a bottom surface of heatsink interposer 130.

In another implementation, higher power than a standard power for POP structure 100 can be used on the bottom package while the heat produced by the higher power can be dissipated using heatsink interposer 130.

In another implementation, heatsink interposer 130 can be used as a stiffener to reduce warpage of bottom package 120 and help on the mounting of bottom package 120 to POP structure 100.

Although FIGS. 1A and 1B show example components of POP structure 100, in other embodiments, POP structure 100 may include fewer components, different components, differently arranged components, or additional components than depicted in FIGS. 1A and 1B.

For example, although FIGS. 1A and 1B show POP structure 100 as a two-stacked structure with heatsink interposer 130, in other embodiments, POP structure 100 may be implemented to include more stacks in the POP structure 100.

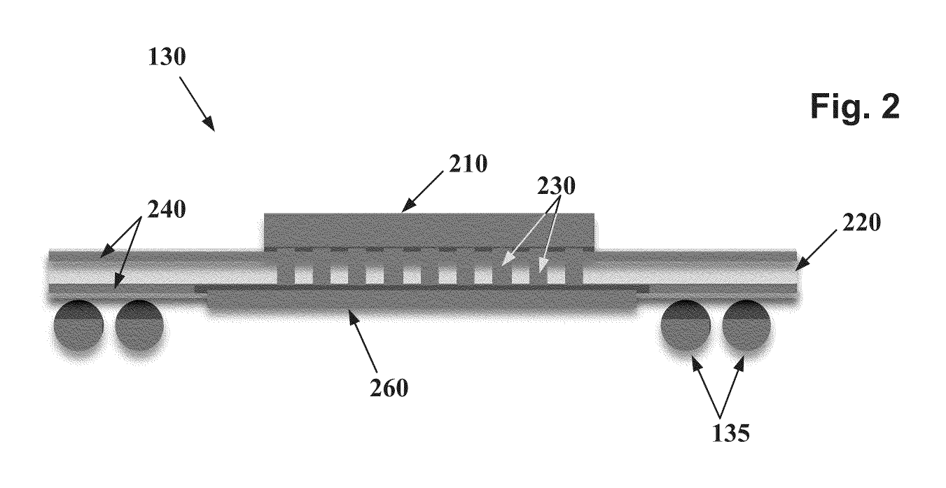

FIG. 2 is a diagram of example components of a heatsink interposer 130 that may be included in POP structure 100. Heatsink interposer 130 may include a top heatsink 210, an interposer substrate 220 with interposer substrate vias 230, interposer substrate metal layers 240, interposer solder balls 135, and a bottom heatsink 260. In one implementation, heatsink interposer 130 may range from 10-17 mm in length and width, and may have a thickness of 500-1000 microns. For example, a heatsink interposer 130 can be 12 mm×12 mm with a thickness of 500 microns.

Top heatsink 210 and bottom heatsink 260 may be provided in heatsink interposer 130 to provide thermal conduction between heatsink interposer 130 and top package 110 and bottom package 120, as well as to provide thermal dissipation and structural integrity. In one embodiment top heatsink 210 may or may not be in thermal communication with top package 110 and bottom heatsink 220 can be in thermal communication with bottom package 120.

Top heatsink 210, material filling interposer substrate vias 230, interposer substrate metal layers 240, and bottom heatsink 260 may include any conductive material, such as a metal (e.g., copper, aluminum, metal alloy) or a non-metal (e.g., diamond, copper-tungsten pseudoalloy, AlSiC (silicon carbide in aluminum matrix)) material. In one implementation, top heatsink 210, material filling interposer substrate vias 230, interposer substrate metal layers 240, and bottom heatsink 260 may be the same or different materials. For example, top heatsink 210, material filling interposer substrate vias 230, interposer substrate metal layers 240, and bottom heatsink 260 may be formed of copper.

Top heatsink 210 and bottom heatsink 260 may be any size in width, length, or height. In one implementation, top heatsink 210 and bottom heatsink 260 and can be 10-17 mm in length and width, top heatsink 210 can be 100-300 microns, and bottom heatsink can be 50-150 microns. For example, top heatsink 210 and bottom heatsink 260 can be 12 mm×12 mm×200 microns. Additionally, or alternatively, as illustrated in FIG. 2, top heatsink 210 can be different in height, width, and/or length from bottom heatsink 260. For example, top heatsink 210 can be 12 mm×12 mm×200 microns and bottom heatsink 260 can be 10 mm×10 mm×100 microns.

Additionally, or alternatively, top heatsink 210 can be customized in size to accommodate solder balls from top package 110. For example, top heatsink 210 can be 10 mm×10 mm for a 15 mm×15 mm top package 110 with an area between solder balls of 11 mm×11 mm, so that top heatsink 210 can fit within the area between the solder balls of top package 110.

Additionally, or alternatively, bottom heatsink 260 can be customized in size and shape to accommodate any portion of bottom package 110, including a die 125. In one implementation, bottom heatsink 260 can be sized larger than a die 125 from bottom package 110. For example, for a bottom package with a die 125 of 10 mm×10 mm×100 microns, bottom heatsink 260 can be 12 mm×12 mm×200 microns.

Interposer substrate 220 can provide insulating and stiffening properties to interposer heatsink 130. Interposer substrate 220 may include any insulating material including a rigid material such as glass-reinforced epoxy laminate sheets (e.g., FR-4), Bismaleimide-Triazine (BT-Epoxy), Ajinomoto Build-Up Film (ABF), or any available industry substrate dielectric material. In one implementation, interposer substrate 220 may be 400-750 micron in height and may be the same length and width as heatsink interposer 130. For example, interposer substrate 220 may be 12 mm×12 mm×500 microns.

Interposer substrate vias 230 can be found in interposer substrate 220 to provide heat dissipation and/or electrical connection ability between top and bottom interposer substrate metal layers 240 and the heatsink interposer 130. In one implementation, interposer substrate vias 230 may be cylindrical or rectangular in shape and can be through holes in interposer substrate 220. Interposer substrate vias 230 can range in diameter or width from 200-400 microns. For example, interposer substrate vias 230 can be 300 microns in diameter.

Material can be used to completely or partially fill interposer substrate vias 230 to improve thermal conduction. In one implementation, interposer substrate vias 230 can be filled with the same material as the top heatsink 210, interposer substrate metal layers 240, and bottom heatsink 260, as mentioned above. For example, interposer substrate vias 230 may be filled with copper.

Additionally, or alternatively, material can be used to completely fill interposer substrate vias 230. For example, interposer substrate vias 230 can be at least partially filled by a conductive material to disperse heat from bottom heatsink 260.

Interposer substrate metal layers 240 may be located between top heatsink 210 and interposer substrate 220 and may be located between bottom heatsink 260 and interposer substrate 220. Interposer substrate metal layers 240 may also be located between interposer substrate 220 and interposer solder balls 135. In one implementation, interposer metal layers 240 may be 25-75 microns. For example, interposer metal layers may be 50 microns. Interposer substrate metal layers 240 can be patterned to provide electrical connections between top and bottom interposer substrate metal layers 240 and to accommodate the electrical connections to top package 110 and bottom package 120.

Interposer solder balls 135 may include any number of solder balls in any size that assists in heat transfer from the bottom package 120 to the heatsink interposer 130. Interposer solder balls 135 may also provide electrical connections between the bottom package 120 and the heatsink interposer 130. Interposer solder balls 135 can be customized in size and pattern to accommodate any portion of bottom package 110, including a die 125. In one implementation, interposer solder balls 135 can have a diameter of 200-400 microns and can be sized to be the same or different in material and diameter compared to solder balls of top package 110 and bottom package 120. For example, interposer solder balls can be 300 microns. Interposer solder balls 135 may be made of any soldering material, such as SAC305 (Sn, Ag, Cu, such as 96.5% Sn, 3% Ag, 0.5% Cu).

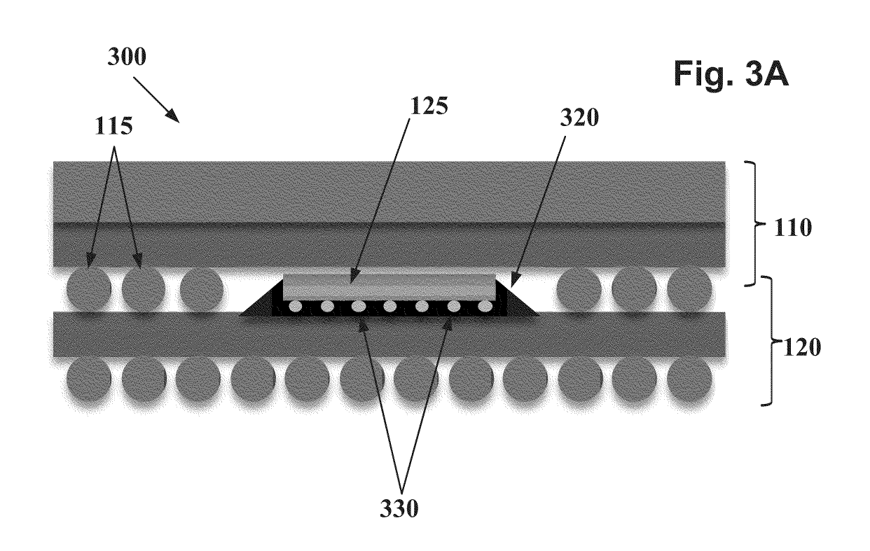

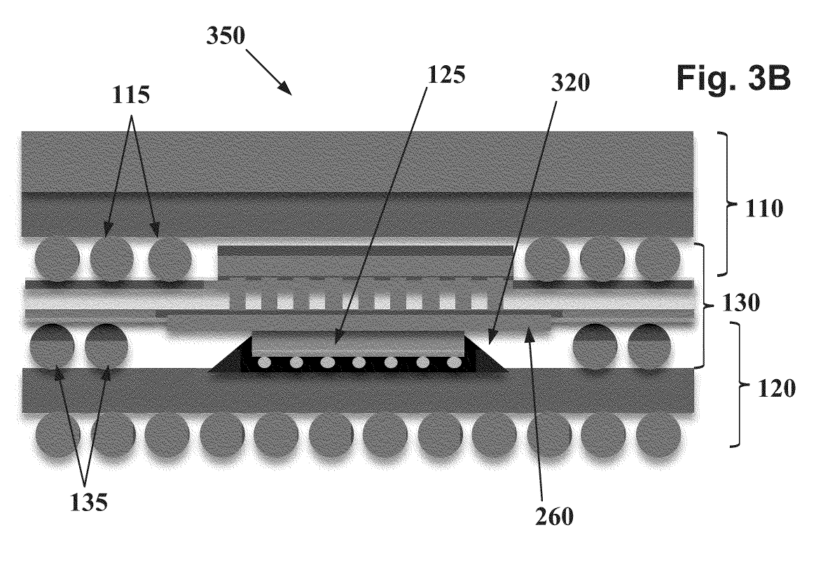

As illustrated in FIGS. 3A and 3B, heat interposer 130 can be used with a POP structure including capillary underfill (CUF).

As illustrated in FIG. 3A, POP structure 300 can include a top package 110, a bottom package 120, die 125 placed on top of bottom package 120, CUF 320 to package interconnections 330, and top package solder balls 115 to separate and electrically connect top package 110 and bottom package 120.

As illustrated in FIG. 3B, heatsink interposer 130 can be used with POP structure 350 including CUF. Heatsink interposer 130 can be placed between top package 110 and bottom package 120 and on top of die 125. Interposer solder balls 135 can be placed between heatsink interposer 130 and bottom package 120. Top package solder balls 115 can be placed between top package 110 and heatsink interposer 130.

In one implementation, heatsink interposer 130 can have a bottom heatsink 260 with a larger horizontal area than die 125 to provide uniform heat transfer from die 125 to heatsink interposer 130. In one implementation, CUF 320 can cover any portion of die 125 and interposer solder balls 135 can be placed on heatsink interposer 130 with sufficient space for CUF 320 to not contact with interposer solder balls 135.

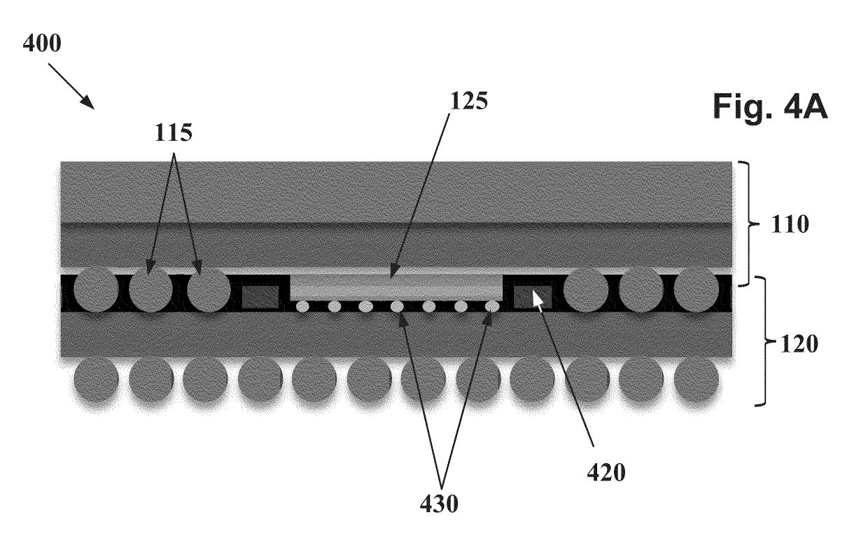

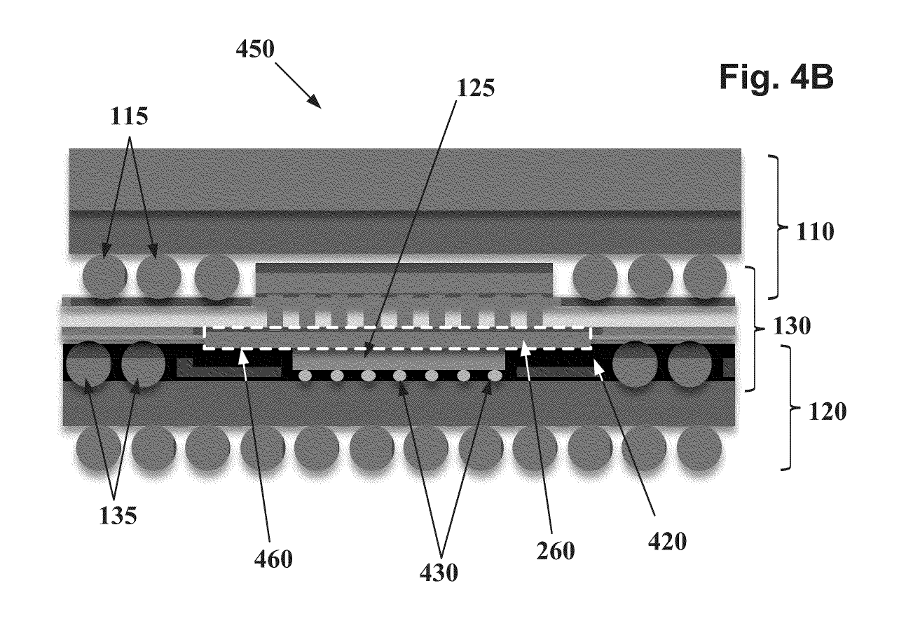

As illustrated in FIGS. 4A and 4B, heat interposer 130 can be used with a POP structure including mold underfill (MUF).

As illustrated 4A, POP structure 400 can include a top package 110, a bottom package 120, die 125 can be placed below top package 110, MUF 420 can cover package interconnections 430, and top package solder balls 115 can separate and electrically connect top package 110 and bottom package 120.

As illustrated in FIG. 4B, heatsink interposer 130 can be used with POP structure 450 including MUF. In FIG. 4B, heatsink interposer 130 can be placed on top of die 125, interposer solder balls 135 can be placed between heatsink interposer 130 and bottom package 120, and top package solder balls 115 can be placed between top package 110 and heatsink interposer 130. In one implementation, heatsink interposer 130 can have a bottom heatsink 260 with a larger horizontal area 460 (outlined) than die 125 to provide heat transfer from die 410 to heatsink interposer 130.

Additionally, or alternatively, MUF 420 can be in contact with bottom heatsink 260 and interposer solder balls 135. In one implementation, as illustrated in FIG. 4B, MUF 420 can cover die 125 and package interconnections 430, and be in contact with bottom heatsink 260 and interposer solder balls 135. Additionally, or alternatively, MUF 420 can partially or completely package interposer solder balls 135. For example, can be provided for packaging die 125 and package interconnections 430 after interposer solder balls 135 are placed on bottom package 120.

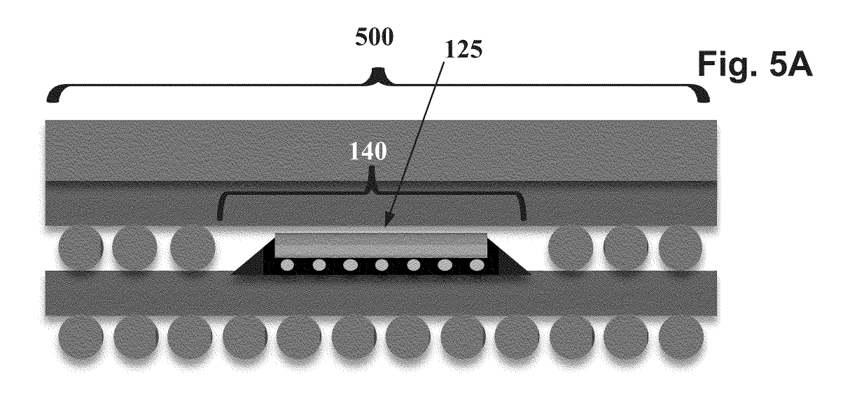

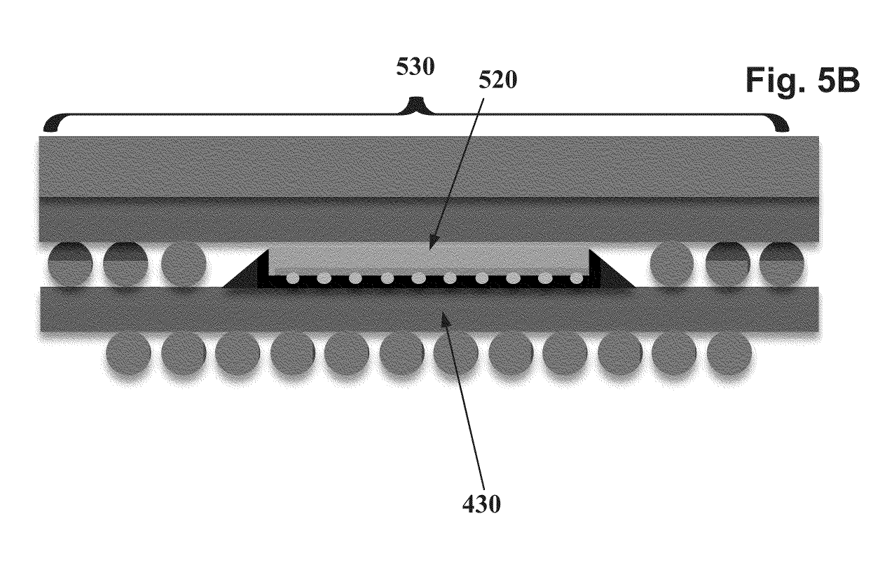

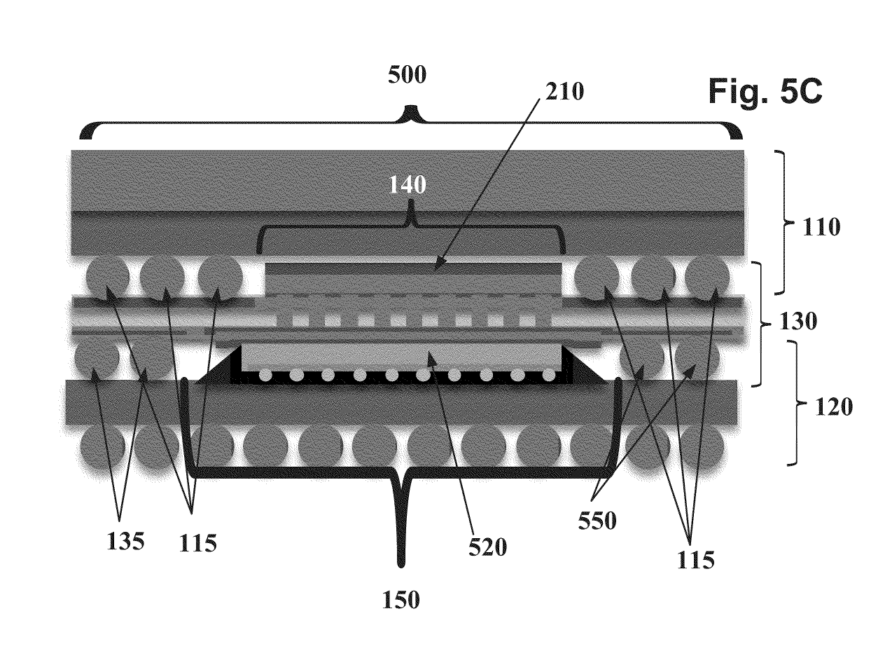

As illustrated in FIGS. 5A-5C, increasing die size from a smaller die 125 in FIG. 5A to a larger die 520 in FIG. 5B could conventionally lead to a larger package size 530, as illustrated in FIG. 5B, compared to the original package size 500 in FIG. 5A. However, using heatsink interposer 130, as illustrated in FIG. 5C, increasing the die size to larger die 520 can be done without changing the width or length of the original package 500 by providing an interposer structure to accommodate the larger die 520 in FIG. 5B and the area between top solder balls 115.

In one implementation, as illustrated in FIG. 5C, interposer solder balls 135 can be placed on heatsink interposer 120 to accommodate a larger die 520 by moving interposer solder balls 135 to create an area for larger die 520 to fit. For example, interposer solder balls 135 can be placed to provide a larger area 150 between interposer solder balls 135 than an area 140 between top package solder balls 115, and larger die 520 can be accommodated by area 150 but not area 140.

Additionally, or alternatively, the size and shape of top heatsink 210 can be customized to allow for top package solder balls 115 to remain the same or be changed. In one implementation, top package solder balls 115 can be positioned in their same locations with the same area 140 between top package solder balls 115. For example, as illustrated in FIGS. 5A and 5C, area 140 can be the same width and length even though die 125 is increased in width and length to larger die 520.

By allowing the size of original package 500 to be maintained, the size of top package 110 can also be maintained. By maintaining the size of top package 110, new and/or different top packages 110 do not have to be provided in order to compensate for the larger die 520 size if a larger die is used.

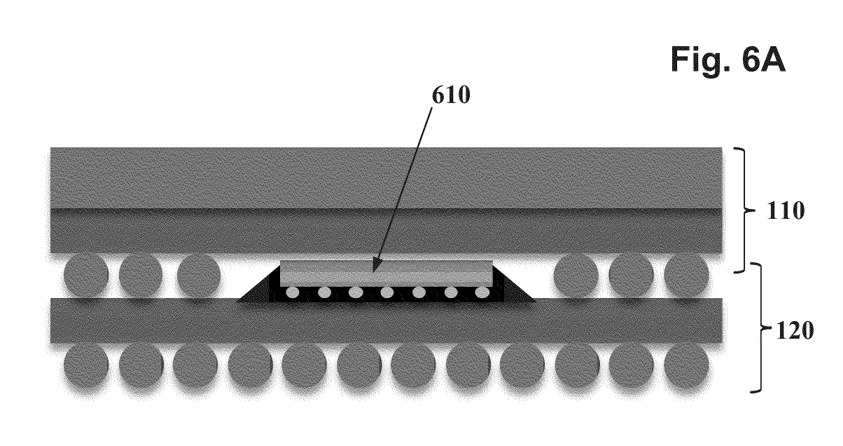

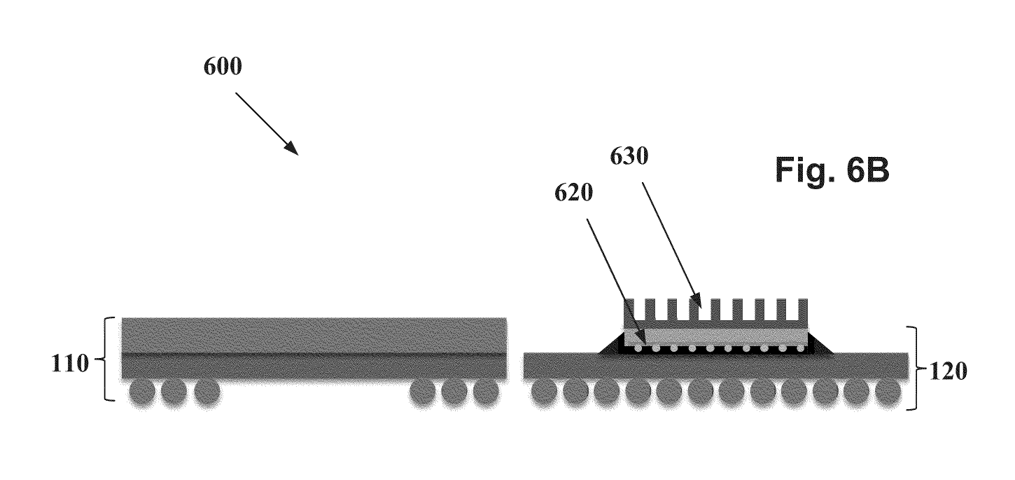

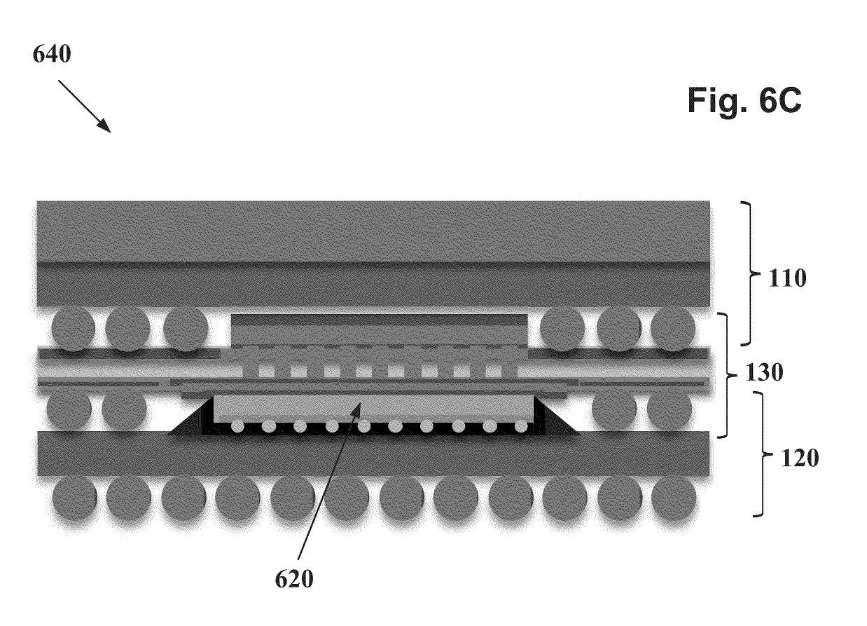

As illustrated in FIGS. 6A-6C, increasing die size from a smaller die 610 in FIG. 6A to a larger die 620 in FIG. 6B and/or increasing power from the power used for the original POP structure in 6A can increase the heat in bottom package 120. In order to dissipate the increased heat, heatsink 630, as illustrated in FIG. 6B can be provided. The addition of heatsink 630 to a structure has conventionally led to a side-by-side structure 600, as illustrated in FIG. 6B. Side-by-side structures can be less than ideal because they tend to have larger horizontal footprints than vertically-stacked POP structures.

As illustrated in FIG. 6C, heat sink interposer 130 can be provided to dissipate heat similar to heatsink 630, and allow for POP structure 600 to be vertically-stacked.

In one implementation, POP structure 640 can be provided with substantially identically sized top package 110, bottom package 120, and heatsink interposer 130. For example, each of the top package 110, bottom package 120, and heatsink interposer 130 can be 15 mm×15 mm×1000 microns. In another implementation, POP structure 100 can be provided with three different sized top package 110, bottom package 120, and heatsink interposer 130. For example, each of the top package 110 can be a 10 mm×10 mm×800 microns, bottom package 120 can be a 12 mm×12 mm×500 microns, and heatsink interposer 130 can be a 12 mm×12 mm×1000 microns.

Systems and/or methods described herein may utilize a heatsink interposer in a POP structure to provide temperature regulation, accommodation of die sizes for varying sized top and bottom packages, and provide increased stiffness. The heatsink interposer may be used with POP structures that utilize CUF or MUF. The heatsink interposer may be used to accommodate larger die sizes and/or increased power, while maintaining package size overall, as well as top package size. The heatsink interposer can also be used as a stiffener to reduce warpage of the bottom package and help with the mounting of the top package to the POP structure. The heatsink interposer can also be used to lower the temperature of the POP structure, especially the bottom package when higher power is used on the bottom package.

The foregoing description of embodiments provides illustration and description, but is not intended to be exhaustive or to limit the claims to the precise form disclosed. Modifications and variations are possible in light of the above disclosure or may be acquired from practice of implementations described herein.

Even though particular combinations of features are recited in the claims and/or disclosed in the specification, these combinations are not intended to limit the disclosure of the possible implementations. In fact, many of these features may be combined in ways not specifically recited in the claims and/or disclosed in the specification. Although each dependent claim listed below may directly depend on only one other claim, the disclosure of the possible implementations includes each dependent claim in combination with every other claim in the claim set.

No element used in the present application should be construed as critical or essential to an implementation unless explicitly described as such. Also, as used herein, the article “a” is intended to include one or more items. Where only one item is intended, the term “one” or similar language is used. Further, the phrase “based on” is intended to mean “based, at least in part, on” unless explicitly stated otherwise.

1. A device, comprising:
a package-on-package structure including a top package and a bottom package,
the bottom package including a die on a top surface of the bottom package; and
a heatsink interposer located between the top package and the bottom package,
the heatsink interposer including:
a heatsink,
an interposer substrate,
the die being located between the interposer substrate and the top surface of the bottom package, and
interposer solder balls on a bottom surface of the interposer substrate,
the die being located in an area between the interposer solder balls on the bottom surface of the interposer substrate.

2. The device of claim 1, where the heatsink includes:
a top heatsink between the top package and the interposer substrate, and
a bottom heatsink between the bottom package and the interposer substrate,
the die being located between the bottom heatsink and the interposer substrate, and
where the top heatsink and the bottom heatsink provide thermal conduction between the heatsink interposer and the top package and the bottom package.

3. The device of claim 2, where a shape and a size of the top heatsink correspond to thermal requirements of the bottom package, and
where a shape and a size of the bottom heatsink correspond to thermal and contact requirements of the bottom package.

4. The device of claim 2,
where the top package further includes solder balls on a bottom surface of the top package, and
where the die is larger than an area between the solder balls on the bottom surface of the top package.

5. The device of claim 2,
where the die is smaller than the area between the interposer solder balls on the bottom surface of the interposer substrate.

6. The device of claim 2, where the die of the bottom package has a thermal dissipation level requirement, and
where the heatsink interposer has a thermal dissipation level at least as high as the thermal dissipation level requirement of the die of the bottom package.

7. The device of claim 1, where the interposer substrate includes:
interposer substrate vias, and
material filling the interposer substrate vias.

8. The device of claim 1, where a structural stiffness of the heatsink interposer increases a structural stiffness of the device.

9. The device of claim 1, where the heatsink comprise copper or aluminum.

10. The device of claim 1, where the top package includes:
a top package substrate; and
top package solder balls between the top package substrate and the interposer substrate, and
where the bottom package includes:
interconnects below the die,
the die being located below the heatsink;
a bottom substrate below the interconnects, and
bottom package solder balls below the bottom substrate.

11. The device of claim 1, where the heatsink includes:
a top heatsink between the top package and the interposer substrate, and
a bottom heatsink between the bottom package and the interposer substrate,
the die being located between the interposer substrate and the bottom heatsink, and
where the heatsink interposer further includes:
interposer substrate metal layers between the interposer substrate and the top heatsink and the bottom heatsink; and
interposer solder balls between the interposer substrate metal layers and the bottom package, and
where the interposer substrate includes vias at least partially filled with a thermally and electrically conductive material.

12. The device of claim 11, where each of the top heatsink, the bottom heatsink, the interposer substrate metal layers, and the thermally and electrically conductive material comprises copper or aluminum.

13. The device of claim 11, where the device is a package-on-package memory device.

14. A package-on-package structure, comprising:
a top package;
a bottom package,
the bottom package including a die on a top surface of the bottom package; and
a heatsink interposer located between the top package and the bottom package,
the heatsink interposer including:
an interposer substrate,
the die being located between the interposer substrate and the top surface of the bottom package,
a top heatsink between the top package and the interposer substrate,
a bottom heatsink between the bottom package and the interposer substrate, and
solder balls, on a bottom surface of the interposer substrate, between the bottom package and the interposer substrate,
the die being located in an area between the solder balls on the bottom surface of the interposer substrate.

15. The structure of claim 14, where a shape and a size of the top heatsink correspond to thermal requirements of the bottom package, and
where a shape and a size of the bottom heatsink correspond to thermal and contact requirements of the bottom package.

16. The structure of claim 14,
where the top package further includes solder balls on a bottom surface of the top package, and
where the die is larger than an area between the solder balls on the bottom surface of the top package.

17. The structure of claim 14, and
where the die is smaller than the area between the solder balls on the bottom surface of the interposer substrate.

18. The structure of claim 16, where the die of the bottom package has a thermal dissipation level requirement, and
where the heatsink interposer has a thermal dissipation level at least as high as the thermal dissipation level requirement of the die of the bottom package.

19. The structure of claim 14, where the top package includes:
a top package substrate, and
top package solder balls between the top package substrate and the interposer substrate, and
where the bottom package includes:
interconnects below the die,
the die being located below the bottom heatsink of the heatsink interposer;
a bottom substrate below the interconnects, and
bottom package solder balls below the bottom substrate.

20. The structure of claim 19, where the bottom package further includes:
molding around the interconnects,
where the molding is capillary underfill (CUF) or mold underfill (MUF),
where, when the molding is CUF, the CUF covers portions of the interconnects and portions of the die, and
where, when the molding is MUF, the MUF covers portions of the interconnects, portions of the die, and portions of the interposer solder balls.

21. A package-on-package heatsink interposer comprising:
a top heatsink below a top package of a package-on-package device;
an interposer substrate below the top heatsink;
a bottom heatsink below the interposer substrate;
a first interposer substrate metal layer between the interposer substrate and the top heatsink;
a second interposer substrate metal layer between the interposer substrate and the bottom heatsink; and
interposer solder balls, on the interposer substrate, between the second interposer substrate metal layer and a bottom package of the package-on-package device,
the bottom package including a die on a top surface of the bottom package,
the die being located, between the bottom heatsink and the bottom package, in an area between the interposer solder balls.
